(19) United States
(12) Patent Application Publication
(10) Pub. No.: US 2025/0294807 A1
(43) Pub. Date: Sep. 18, 2025

(54) DOUBLE GATED THIN FILM TRANSISTOR INTEGRATION

(71) Applicant: Applied Materials, Inc., Santa Clara, CA (US)

(72) Inventor: Milan Pesic, Paoli, PA (US)

(73) Assignee: Applied Materials, Inc., Santa Clara, CA (US)

(21) Appl. No.: 18/606,700

(22) Filed: Mar. 15, 2024

(51) Int. Cl. H01L 29/786; H01L 29/66

(52) U.S. Cl. CPC H10D 30/6733; H10D 30/0321; H10D 30/6755

(57) ABSTRACT

A dual-gate device can control display pixels, such as LED-based pixels. The dual-gate device can include two thin-film transistors (TFTs). A first TFT or top gate structure can be deposited directly on a second TFT or bottom gate structure. The first TFT can include a first conducting layer, a first gate insulator, and a semiconductor structure. The semiconductor structure can include a source and a drain. The second TFT can include the semiconductor structure, a second gate insulator, and a second conducting layer. By stacking the first TFT on top of the second TFT, a fabrication process can involve fewer masks and less expense than processes that involve forming the two TFTs separately or on separate portions of a substrate.

### TECHNICAL FIELD

This disclosure generally describes drive circuitry for display pixels. More specifically, this disclosure describes dual-gate devices that can switch and drive diode-based pixel outputs.

### BACKGROUND

Pixels of displays for many devices can include a control circuit. Drive circuitry for a single light emitting diode (LED)-based pixel can include a dual transistor configuration. The dual transistor configuration can include a switching thin film transistor (S-TFT) and a driving thin film transistor (D-TFT). The S-TFT can turn the pixel on or off and the D-TFT can control an intensity or brightness of the pixel. A fabrication method for pixels involving drive circuitry with a dual transistor configuration can be complex and can include additional fabrication steps with many different masks.

### BRIEF SUMMARY

In some embodiments, a dual-gate device may include a first gate structure including a first conducting layer; a first insulating layer beneath the first conducting layer; and a semiconductor structure under the first insulating layer. The semiconductor structure may include a source and drain region. The dual-gate device may also include a second gate structure including the semiconductor structure and a second insulating layer under the semiconductor structure. The second insulating layer may include a plurality of dielectric layers. At least one layer of the plurality of dielectric layers may have a different dielectric constant than any other layer in the plurality of dielectric layers. The second gate structure may include a second conducting layer beneath the second insulating layer.

In some embodiments, a method for fabricating a dual-gate device may include forming a first gate structure by forming and patterning a first conducting layer and forming a first insulating layer. The first insulating layer may include a plurality of dielectric layers. At least one layer of the plurality of dielectric layers may have a different dielectric constant than any other layer in the plurality of dielectric layers. Forming the first gate structure may also include forming and patterning a semiconductor structure that may include a source and drain region. The method may also include forming a second gate structure by forming and patterning a second insulating layer; and forming and patterning a second conducting layer.

In any embodiments, any and/or all of the following features may be implemented in any combination and without limitation. The first gate structure may include a steeper subthreshold slope than the second gate structure. The first insulating layer may include a larger dielectric constant than an effective dielectric constant of the second insulating layer. The plurality of dielectric layers may include three dielectric layers. The three dielectric layers may include a first silicon oxide layer, a doped silicon oxide layer, and a second silicon oxide layer. The doped silicon oxide layer may be doped with carbon or fluorine. The three dielectric layers may include a first silicon oxide layer, an oxygen depleted layer, and a second silicon oxide layer. The first or the second silicon oxide layer may be less than about 20 nanometers thick. The semiconductor structure may include a first metal oxide semiconductor thin film and a second metal oxide semiconductor thin film under the first metal oxide semiconductor thin film. The semiconductor structure may include a third metal oxide semiconductor thin film under the second metal oxide semiconductor thin film. The third metal oxide semiconductor thin film may be identical to the first metal oxide semiconductor thin film. The plurality of dielectric layers may include three dielectric layers. The three dielectric layers may include a first silicon oxide layer, a doped silicon oxide layer, and a second silicon oxide layer. Forming the first insulating layer may include forming a first silicon oxide layer; forming a layer of carbonated or fluorinated amorphous silicon; forming a doped silicon oxide layer from at least a portion of the first silicon oxide layer by annealing the carbonated or fluorinated amorphous silicon, the doped silicon oxide layer being doped with carbon or fluorine; etching the annealed amorphous silicon layer; and forming a second silicon oxide layer. Forming the first insulating layer may include forming a first silicon oxide layer; forming an oxygen depleted layer; and forming a second silicon oxide layer. Forming the oxygen depleted layer may include forming the oxygen depleted layer by adjusting a silicon to oxygen ratio in a silicon oxide forming process or by depositing a titanium oxide layer with at least one pulse of a laser. The first or second silicon oxide layer may be less than 20 nanometers thick. Forming and patterning the semiconductor structure may include forming and patterning a first metal oxide semiconductor thin film; forming and patterning a second metal oxide semiconductor thin film; and forming and patterning a third metal oxide semiconductor thin film, the third metal oxide semiconductor thin film being formed under the first metal oxide semiconductor thin film. The third metal oxide semiconductor thin film may be identical to the first or second metal oxide semiconductor thin film.

### BRIEF DESCRIPTION OF THE DRAWINGS

FIG. 1 is a circuit diagram of a control circuit for a display pixel according to some embodiments.

FIG. 2 is a graph that shows current-gate voltage characteristics for different thin film transistors according to some aspects of the present disclosure.

FIG. 3 is a cross-section of a dual-gate device for controlling a display pixel according to some embodiments.

FIG. 4 is a diagram of a multilayer capacitor according to some embodiments.

FIG. 5 is a cross-section of a dual-gate device with a D-TFT bottom gate structure consistent with a first or second approach according to some embodiments.

FIG. 6 is a cross-section of a dual-gate device with a D-TFT bottom gate structure consistent with a third approach according to some embodiments.

FIG. 7 is a is a graph that shows current-gate voltage characteristics for different thin film transistors consistent with a third approach according to some embodiments.

FIG. 8 is a cross-section of a dual-gate device with a D-TFT bottom gate structure consistent with a fourth approach according to some embodiments.

FIG. 9 is a graph of energy band diagrams as a function of a coordinate z associated with a dual-gate device consistent with a fourth approach according to some embodiments.

FIG. 10 is a graph of electron density as a function of a coordinate z associated with a dual-gate device consistent with a fourth approach according to some embodiments.

FIG. 11 is a flow chart of an example of a process for fabricating a dual-gate device according to some embodiments.

FIG. 12 is a flow chart of an example of a process for fabricating multiple dielectric layers of a first insulating layer in a dual-gate device according to some embodiments.

FIG. 13 is a flow chart of an example of a process for fabricating a first insulating layer having an oxygen depleted layer in a dual-gate device according to some embodiments.

### DETAILED DESCRIPTION

Certain aspects and examples of the present disclosure relate to a dual-gate device that can control display pixels, such as LED-based pixels. The dual-gate device can include two TFTs. A first TFT or top gate structure can be deposited directly on a second TFT or bottom gate structure. The first TFT can include a first conducting layer, a first gate insulator, and a semiconductor structure. The semiconductor structure can include a source and a drain. The second TFT can include the semiconductor structure, a second gate insulator, and a second conducting layer. By stacking the first TFT on top of the second TFT, a fabrication process can involve fewer masks and less expense than processes that involve forming the two TFTs separately or on separate portions of a substrate.

The two TFTs of the dual-gate device can control the LED-based pixel. One of the TFTs can act as a S-TFT that turns the pixel on or off. The other TFT can act as the D-TFT and can control an intensity of brightness of the pixel. The intensity of the pixel can be associated with a source-drain current of the D-TFT. Although several examples in this disclosure can describe a dual-gate device with a top gate S-TFT and a bottom gate D-TFT (referred to as top gate switching), the bottom gate can be designed to control switching as well. That is, the bottom gate can be designed to act as the S-TFT and the top gate can act as the D-TFT. Descriptions of the top gate switching device included in this disclosure can enable a person of ordinary skill in the art to design and fabricate a bottom gate switching device and vice versa.

The TFT of the dual-gate device that acts as the S-TFT can be designed to adequately switch a pixel on or off. The S-TFT structure of the dual-gate device can include certain characteristics, such as relatively low leakage current, fast switching, and current-gate voltage (I-V_{G}) characteristics that include a steep subthreshold slope. The gate insulating layer of the S-TFT portion of the dual-gate structure can be designed with a maximized effective dielectric constant and minimized trapped charges. Although several examples of a top gate S-TFT structure are shown in the following figures, the bottom gate structure can also be designed to act as the S-TFT.

The TFT of the dual-gate device that acts as the D-TFT can be engineered to control brightness or intensity of the pixel. The D-TFT structure of the dual-gate device can include certain characteristics, such as I-V_{G} characteristics that include a small or shallow subthreshold slope. The subthreshold slope of the D-TFT can be less than the subthreshold slope of the S-TFT in the dual-gate device. Various examples of methods for producing a shallow subthreshold slope in the D-TFT are shown in the present disclosure.

The gate insulating layer of the D-TFT portion of the dual-gate structure can be designed with a minimized effective dielectric constant. The effective dielectric constant of the D-TFT insulating layer can be lower than the effective dielectric constant of the S-TFT portion of the dual-gate device. The D-TFT insulating layer can be thicker than the S-TFT insulating layer. For example, the D-TFT insulating layer can be 300-400 nm thick and the S-TFT insulating layer can be 100-200 nm thick. The D-TFT insulating layer can include multiple layers and each of the layers can be made from a low-k dielectric material. In some examples, the D-TFT insulating layer can include three layers and at least one of the layers can have a different dielectric constant than the other layers.

In one example of a dual-gate pixel controller, the D-TFT insulating layer can include a bottom layer of silicon oxide, a middle layer of silicon oxide doped with carbon or fluorine atoms, and a top layer of silicon oxide. A presence of the carbon or fluorine atoms can cause the middle layer to have a lower dielectric constant than the bottom and top layers. In another example, the D-TFT insulating layer can include a bottom silicon oxide layer, an oxygen depleted middle layer, and a top silicon oxide layer. The top silicon oxide layer can be a very thin (e.g., 5-20 nm) layer. The oxygen depleted layer can introduce trapped charges in the D-TFT insulating layer near a channel of the semiconductor structure. A presence of the trapped charges can reduce an effectiveness of the D-TFT gate voltage or “shield” the channel from the D-TFT gate voltage and smear the I-V_{G} characteristics to reduce the subthreshold slope of the D-TFT. Although several examples of a bottom gate D-TFT structure are shown in the following figures, the top gate structure can also be designed to act as the D-TFT.

The semiconductor structure of the dual-gate device can include multiple semiconductor layers. A bottom semiconductor layer can act as a main channel for both the top gate and bottom gate structures. A top semiconductor layer can act as a protective layer that protects the bottom semiconductor layer from processing steps that can be detrimental to the bottom semiconductor layer. In some examples, the semiconductor structure can include a third semiconductor layer, under the main channel layer, that can act as an additional protective layer.

Materials that can form any of the semiconductor layers of the dual-gate device can include metal oxide semiconductor thin films, low temperature polysilicon (LTPS), etc. Examples of metal oxide semiconductors can include n-type metal oxide semiconductors, such as Indium (III) Oxide (In₂O₃), Zinc Oxide (ZnO), or Tin (IV) Oxide (SnO₂). Examples of metal oxide semiconductors can also include p-type metal oxide semiconductors, such as Copper (II) Oxide (CuO), Nickel Oxide (NiO), Chromium Oxide (Cr₃O₄), or Cobalt (II, III) Oxide (Co₃O₄).

Illustrative examples are given to introduce the reader to the general subject matter discussed herein and are not intended to limit the scope of the disclosed concepts. The following sections describe various additional features and examples with reference to the drawings in which like numerals indicate like elements, and directional descriptions are used to describe the illustrative aspects, but, like the illustrative aspects, should not be used to limit the present disclosure.

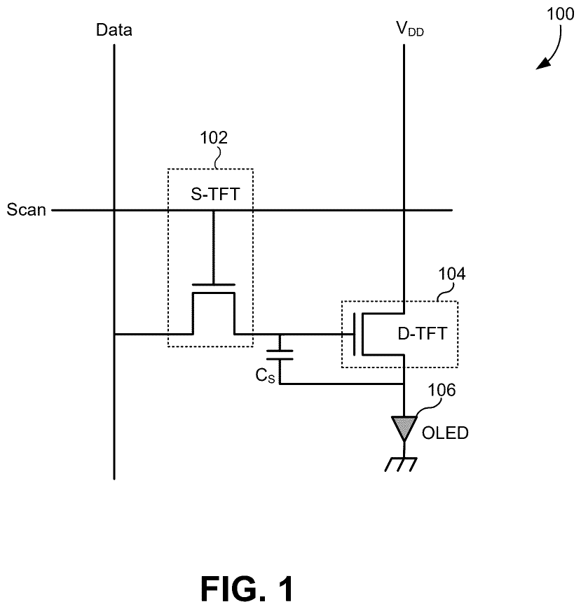

FIG. 1 is a circuit diagram of a control circuit 100 for a display pixel according to some aspects of the present disclosure. The display pixel can be an organic light-emitting diode (OLED) 106. The control circuit can include an S-TFT 102 and a D-TFT 104. The S-TFT 102 can turn the OLED 106 on or off and the D-TFT 104 can control a brightness or intensity of the OLED 106 based on an electric current flowing through the D-TFT 104.

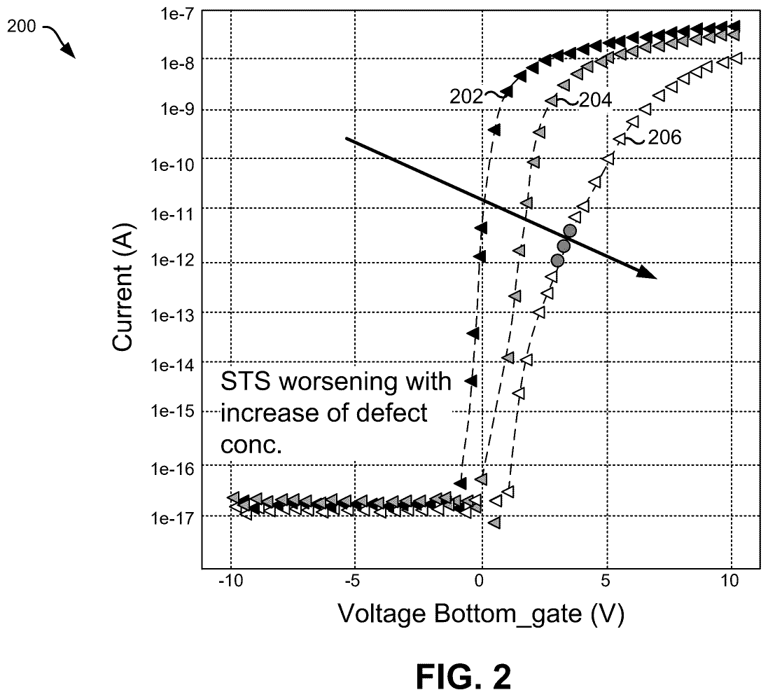

The D-TFT 104 can be engineered to have different properties than the S-TFT 102. For example, the D-TFT 104 can be designed to have different I-V_{G} characteristics than the S-TFT 102. FIG. 2 illustrates a graph 200 that shows current-gate voltage characteristics for different TFTs according to some aspects of the present disclosure. Data for various plots 202-206 of the graph 200 can be formed while maintaining a constant drain to source voltage for each of the different TFTs. As shown in the graph 200, the gate voltage of a TFT can modify a conductance of a channel TFT between two states. The two states can include a high conductance ‘ON’ state and a low conductance ‘OFF’ state. A transition between the two states can be characterized by a subthreshold slope of a current vs. gate voltage plot. Of the three plots 202-206, plot 202 has the steepest subthreshold slope and plot 206 has the smallest subthreshold slope.

To quickly turn the OLED 106 on or off, I-V_{G} characteristics of the S-TFT 102 can include a sharp subthreshold slope like that of plot 202. Conversely, I-V_{G} characteristics of the D-TFT 104 can include a shallow subthreshold slope like that of plot 206. A shallow subthreshold voltage can involve more gate voltage values associated with a change in current for the transistor, making the transistor more tunable. The D-TFT 104 can have a greater range of brightness control of the OLED 106 when the subthreshold slope is made shallower. Different types of transistors can be used for the S-TFT 102 and D-TFT 104, respectively. For example, a metal oxide semiconductor can serve as the S-TFT 102 and a LTPS TFT can act as the D-TFT 104.

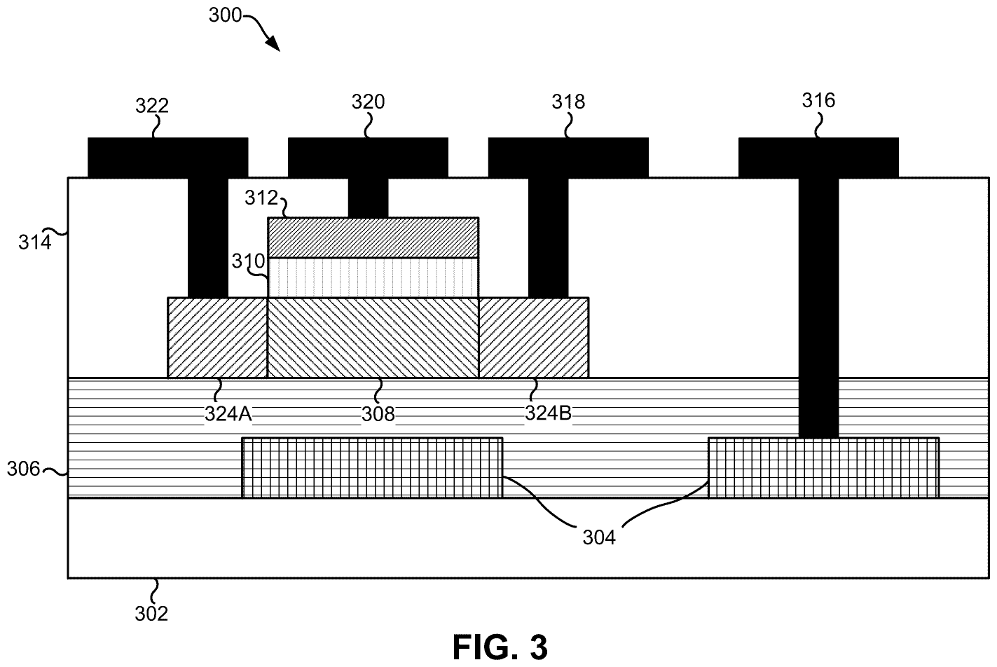

FIG. 3 is a cross-section of a dual-gate device 300 for controlling a display pixel according to some aspects of the present disclosure. The dual-gate device 300 can include a top gate structure and a bottom gate structure. Both the top gate structure and the bottom gate structure can be formed on a buffer layer 302. The bottom gate structure can include a bottom conducting layer 304, a bottom gate insulator 306, and a semiconductor structure 308. The bottom conducting layer 304 can be deposited directly on the buffer layer 302. The bottom gate insulator 306 can be deposited or grown on top of the bottom conducting layer 304. The semiconductor structure 308 can be formed above the bottom conducting layer 304. In some examples, the bottom conducting layer 304, the bottom gate insulator 306, the semiconductor structure 308, or some combination of the three layers can be patterned. The bottom gate structure can act as either an S-TFT or a D-TFT of a control circuit for the display pixel.

The top gate structure can include the semiconductor structure 308, a top gate insulator 310, and a top conducting layer 312. The top gate insulator 310 can be deposited or grown on the semiconductor structure 308. The top conducting layer 312 can be formed above the top gate insulator 310. The top conducting layer 312, the top gate insulator 310, the semiconductor structure 308, or some combination of the three layers can be patterned. The top gate structure can act as either an S-TFT or a D-TFT of a control circuit for the display pixel.

The top conducting layer 312 can be centered above the bottom conducting layer 304. In some examples, the top conducting layer 312 can be patterned to include a width that is less than a width of the bottom conducting layer 304. For example, the width of the bottom conducting layer 304 can be twice the width of the top conducting layer 312. As an example, a range of widths for the top conducting layer 312 can include 2 to 10 microns and a range of widths for the bottom conducting layer 304 can include 4 to 20 microns.

The semiconductor structure 308 of the dual-gate device 300 can include heavily doped regions referred to as a source region 324A and a drain region 324B. In some examples, the semiconductor structure 308 can include multiple semiconductor layers. A bottom semiconductor layer can act as a main channel for both the top gate and bottom gate structures. A top semiconductor layer can act as a protective layer that protects the bottom semiconductor layer from processing steps that can be detrimental to the bottom semiconductor layer. In some examples, the semiconductor structure can include a third semiconductor layer, under the main channel layer, that can act as an additional protective layer. Each of the semiconductor layers can include the source region 324A or drain region 324B.

Materials that can form any of the semiconductor layers of the dual-gate device 300 can include metal oxide semiconductors, low temperature polysilicon (LTPS), etc. Examples of metal oxide semiconductors can include n-type metal oxide semiconductors, such as Indium Gallium Zinc Tin Oxide (IGZTO), Indium (III) Oxide (In₂O₃), Zinc Oxide (ZnO), or Tin (IV) Oxide (SnO₂). Examples of metal oxide semiconductors can also include p-type metal oxide semiconductors, such as Copper (II) Oxide (CuO), Nickel Oxide (NiO), Chromium Oxide (Cr₃O₄), or Cobalt (II, III) Oxide (Co₃O₄). The separate layers of the semiconductor structure 308 can be formed from a single semiconductor structure, a single material formed from different deposition parameters in each layer, or from different materials.

The dual-gate device 300 can also include an interlayer dielectric (ILD) 314 and several vias or contact pads 316, 318, 320, and 322 for making electrical contact with some regions of the dual-gate device 300. The contact pads can include a bottom gate contact pad 316 for making electrical contact with the bottom conducting layer 304, a drain contact pad 318 for making electrical contact with the drain region 324B, a top gate contact pad 320 for making electrical contact with the top conducting layer 312, and a source contact pad 322 for making electrical contact with the source region 324A.

The top gate structure of the dual-gate device 300 can have different device characteristics than the bottom gate structure and vice versa. For example, the top gate structure can have a steep subthreshold slope and act as an S-TFT, while the bottom gate structure can have a shallow subthreshold slope and act as a D-TFT. In other examples, the top gate structure can act as the D-TFT while the bottom gate structure acts as the S-TFT. Techniques and methods can be applied during fabrication to ensure that one of the gate structures is suitable to be the S-TFT and the other gate structure is a suitable D-TFT.

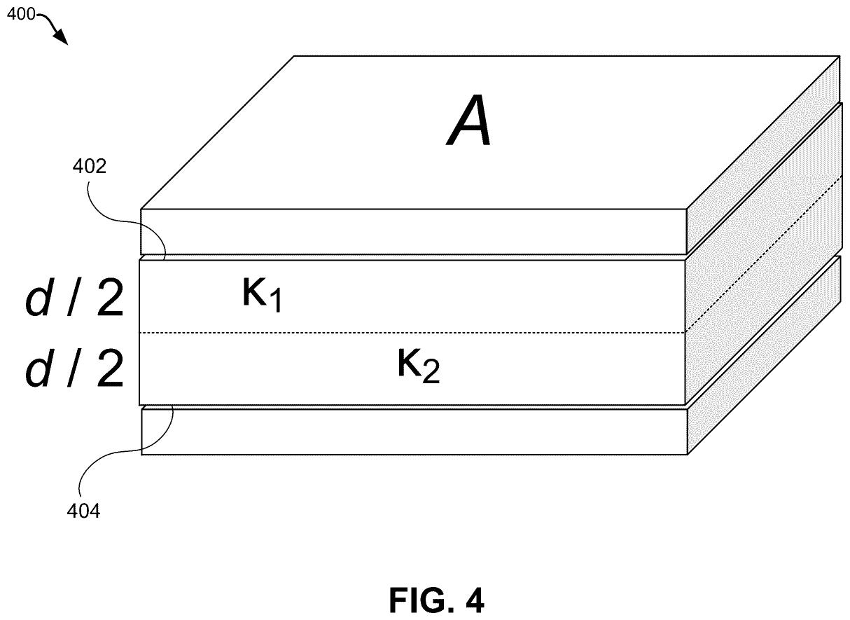

FIG. 4 is a diagram of a multilayer capacitor 400 according to some aspects of the present disclosure. The multilayer capacitor 400 can have a cross sectional area A and a total thickness d. The multilayer capacitor 400 can be a parallel plate capacitor that includes a first dielectric layer 402 and a second dielectric layer 404 sandwiched between two electrodes. The thickness of each of the two layers can be

$$\frac{d}{2} .$$

The first dielectric layer 402 can have a dielectric constant κ₁ and the second dielectric layer 404 can have a dielectric constant κ₂.

In general, capacitance C of a parallel plate capacitor with a single dielectric material is given by the expression:

$$C = κ {ε}_{0} \frac{A}{d} \qquad ( 1 )$$

where κ is the dielectric constant of the single dielectric material and ε₀ is the permittivity of free space and has a constant value of

$$8.854 \times 1 {0}^{- 12} \frac{Fara d s}{meter} .$$

The two dielectric layers of the multilayer capacitor 400 can be treated as two capacitors connected in series. Therefore, a total capacitance C′ of the multilayer capacitor 400 can be expressed as:

$$\frac{1}{{C}^{′}} = \frac{1}{{C}_{1}} + \frac{1}{{C}_{2}} \qquad ( 2 )$$

where C₁ is the capacitance associated with the first dielectric layer 402:

$${C}_{1} = {κ}_{1} {ε}_{0} \frac{A}{d / 2} \qquad ( 3 )$$

and C₂ is the capacitance associated with the second dielectric layer 404:

$${C}_{2} = {κ}_{2} {ε}_{0} \frac{A}{d / 2} \qquad ( 4 )$$

Equation (2) can indicate that the total capacitance C′ of the multilayer capacitor 400 can be less than the capacitances of either of the individual layers. A simplified expression for C′ can be found by substituting equation (3) and equation (4) into equation (2) and solving for C′:

$${C}^{′} = \frac{2 {κ}_{1} {κ}_{2}}{( {κ}_{1} + {κ}_{2} )} {C}_{0} \qquad ( 5 )$$

where:

$${C}_{0} = {ε}_{0} \frac{A}{d} \qquad ( 6 )$$

The next few sections of the present disclosure highlight various approaches for producing a dual-gate device with an S-TFT top gate structure and a D-TFT bottom gate structure. A person of ordinary skill would recognize that similar approaches can be applied to form a dual-gate device with a D-TFT top gate structure and an S-TFT bottom gate structure using this disclosure. Each of the following approaches can be combined with each other approach, multiple approaches, all of the other approaches, etc.

### I. Approach #1: A Multi-Layer Bottom Gate Insulator

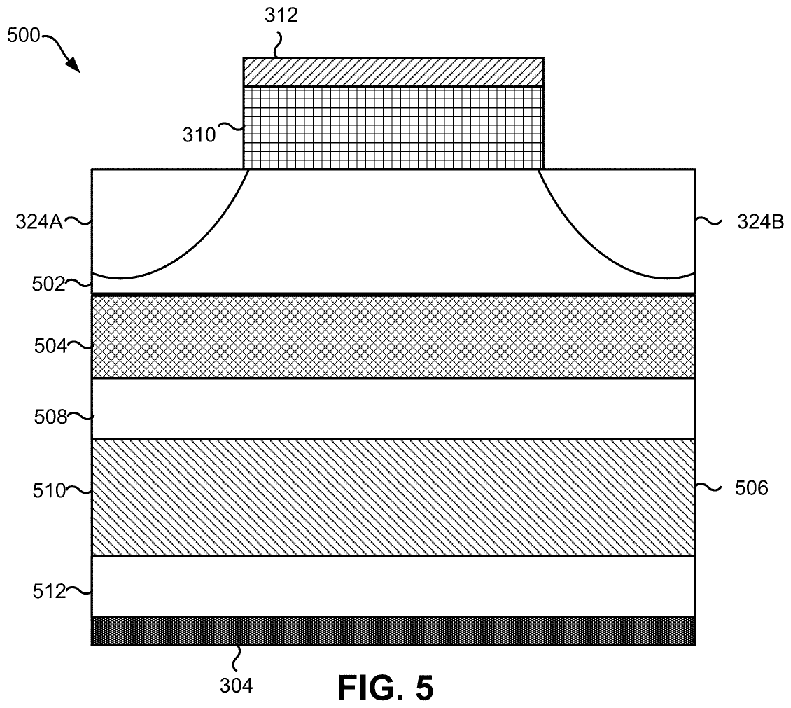

FIG. 5 is a cross-section of a dual-gate device 500 with a D-TFT bottom gate structure consistent with a first or second approach according to some aspects of the present disclosure. The dual-gate device 500 can be an example of dual-gate device 300 from FIG. 3. The first approach for creating the dual-gate device 500 with a D-TFT bottom gate structure and a S-TFT top gate structure can involve a multi-layer bottom gate insulator such as bottom gate insulator 506 of the dual-gate device 500. The D-TFT bottom gate structure of the dual-gate device 500 can also include a bottom conducting layer 304 and a semiconductor structure in addition to the bottom gate insulator 506. The semiconductor structure can include heavily doped regions referred to as a source region 324A and a drain region 324B. The semiconductor structure can also include multiple semiconductor layers, such as semiconductor layer 502 and semiconductor layer 504. In FIG. 5, the source region 324A and the drain region 324B are shown confined to the semiconductor layer 502 but the source region 324A and the drain region 324B can extend into the semiconductor layer 504.

As described above, a small threshold slope can be useful for operations of a D-TFT. The subthreshold slope of the D-TFT bottom gate structure can be related to an effective capacitance of the bottom gate insulator 506. By reducing the capacitance of the bottom gate insulator 506, the subthreshold slope can be reduced. A first approach for forming a D-TFT from the bottom gate structure can involve reducing the effective capacitance of the bottom gate insulator 506 by including multiple layers in the bottom gate insulator 506. The bottom gate insulator 506 can include a top layer 508, a middle layer 510, and a bottom layer 512.

Although FIG. 5 depicts three layers in the bottom gate insulator 506, in some examples, the bottom gate insulator 506 can include two layers or more than three layers. The top layer 508, middle layer 510, and bottom layer 512 can each include different materials and have different dielectric constants. Conversely, the three layers can all be made from the same material but subject to different fabrication techniques so that at least one of the three layers has a modified dielectric constant. The three layers can have different thicknesses. At least one of the layers can have a different dielectric constant than the other two layers. For example, the top layer 508 and the bottom layer 512 can include a same material with a single dielectric constant and the middle layer 510 can have a lower dielectric constant than the other two layers.

The bottom gate insulator 506 can include layers of low k dielectrics/low dielectric constant materials. Examples of low k dielectrics include silicon oxide (SiO₂), porous silicon oxide, spin-on organic polymer films, spin-on silicon based polymeric dielectrics, air gaps, etc. At least one of the layers in the bottom gate insulator 506 can have a lower dielectric constant than that of a single material used as a top gate insulator in the dual-gate device 500.

The dual-gate device 500 can also include a top gate structure. The top gate structure can act as an S-TFT and can have a steeper subthreshold slope than the bottom gate structure. The top gate structure can include the semiconductor structure (including all components of the semiconductor structure), a top gate insulator 310, and a top conducting layer 312. The top gate insulator 310 can include a single dielectric layer or multilayers with less layers than the bottom gate insulator 506. For example, the top gate insulator 310 can include a single layer of silicon oxide. A capacitance of the top gate insulator 310 can be greater than a capacitance of the bottom gate insulator 506. For example, the top gate insulator 310 can be thinner than the bottom gate insulator 506.

II. Approach #2: A Bottom Gate Insulator with a Doped Silicon Oxide Layer

A second approach for forming a D-TFT from the bottom gate structure can involve including a doped silicon oxide layer as one of the layers of the bottom gate insulator. The doped silicon oxide layer can be doped with fluorine or carbon to modify and reduce a dielectric constant of silicon oxide. Fluorine doped silicon oxide can be referred to as fluorosilicate glass. Carbon doped silicon oxide can be referred to as organosilicate glass (OSG).

As an example, a bottom layer 512 of silicon oxide can be grown on the bottom conducting layer 304. The bottom layer 512 of silicon oxide can be grown very thin (˜5-10 nm) to form a good interface with the bottom conducting layer 304. An additional silicon oxide layer can be grown as the middle layer 510. A thin layer of fluorinated amorphous silicon can be deposited on top of the silicon oxide middle layer 510. In some examples, a thin layer of carbonated amorphous silicon can replace the fluorinated amorphous silicon.

The fluorinated amorphous silicon can be annealed. Annealing the fluorinated amorphous silicon layer can cause fluorine atoms to diffuse into the middle layer 510 and modify the middle layer 510. The middle layer 510 can become fluorine doped silicon oxide after the anneal, reducing a dielectric constant of the middle layer 510. After annealing, the fluorinated amorphous silicon layer can be removed via an etch process. Another silicon oxide layer can be deposited on the doped silicon oxide middle layer 510 to form a silicon oxide top layer 508. The top layer 508 can also be grown thin (˜5-10 nm) and form a good interface with semiconductor layer 504.

In some examples, instead of depositing a fluorinated or carbonated silicon layer, the middle layer 510 can be annealed within an environment that is rich in dopant atoms. For example, after the middle layer 510 is deposited, the middle layer 510 can be annealed in nitrogen trifluoride (NF₃). During the anneal in NF₃, fluorine atoms can diffuse into the middle layer 510 to form fluorine doped silicon oxide and the dielectric constant of the middle layer 510 is reduced.

III. Approach #3: A Bottom Gate Insulator with a Defect Layer Near the Semiconductor Structure

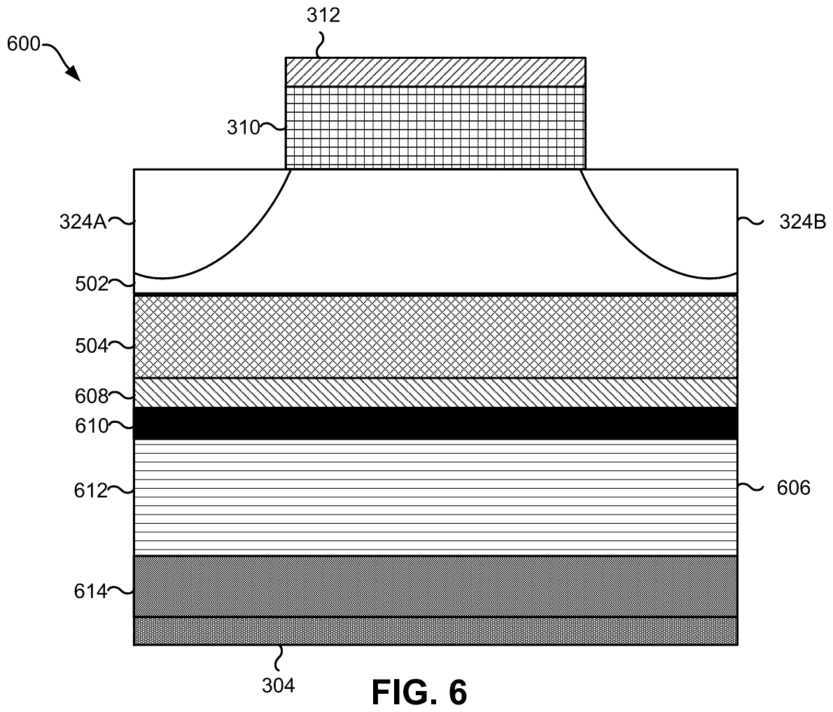

FIG. 6 is a cross-section of a dual-gate device 600 with a D-TFT bottom gate structure consistent with a third approach according to some aspects of the present disclosure. The third approach can involve introducing a defect layer 610 in a bottom gate insulator 606 of the dual-gate device 600. The dual-gate device 600 can be an example of dual-gate device 300 from FIG. 3. The D-TFT bottom gate structure of the dual-gate device 600 can include a bottom conducting layer 304, a semiconductor structure, and the bottom gate insulator 606. The semiconductor structure can include heavily doped regions referred to as a source region 324A and a drain region 324B. The semiconductor structure can also include multiple semiconductor layers, such as semiconductor layer 502 and semiconductor layer 504. In FIG. 6, the source region 324A and the drain region 324B are shown confined to the semiconductor layer 502 but the source region 324A and the drain region 324B can extend into the semiconductor layer 504.

As described above, a small threshold slope can be useful for operations of a D-TFT. By including the defect layer 610 in the bottom gate insulator 606, excess electric charges can be introduced in the bottom gate insulator. If the excess electric charges are kept near the semiconductor structure (e.g., 10-20 nm below semiconductor layer 504), the excess charges can reduce the subthreshold slope of the bottom gate structure. The defect layer 610 can be ultrathin, with a thickness of a single monolayer. The defect layer 610 can be an oxygen depleted layer.

As an example, a bottom layer 614 of silicon oxide can be grown on the bottom conducting layer 304. The bottom layer 614 of silicon oxide can be grown very thin (˜5-10 nm) to form a good interface with the bottom conducting layer 304. An additional silicon oxide layer can be grown as layer 616. In some examples, the layer 616 can be a doped silicon oxide layer consistent with approach #2 described above. The defect layer 610 can be formed in a similar manner as the bottom layer 614 of silicon oxide but a silicon to oxygen ratio can be tuned to cause the defect layer 610 to be an oxygen depleted layer, with oxygen vacancies. For instance, instead of a 1:2 silicon to oxygen ratio, the silicon to oxygen ratio can be 1:1.5 while the defect layer is formed. Alternatively or additionally, the defect layer 610 can be formed from pulsed laser deposition. For example, the defect layer 610 can be a titanium oxide (TiO₂) thin film formed as a monolayer from a single laser pulse. A higher concentration in oxygen vacancies can lead to a greater reduction in the subthreshold slope of the bottom gate structure. Another silicon oxide layer can be deposited on the defect layer 610 to form a silicon oxide top layer 608. The top layer 608 can also be grown thin (˜5-20 nm) to form a good interface with semiconductor layer 504 and to keep defects of the defect layer 610 close to the semiconductor layer 504.

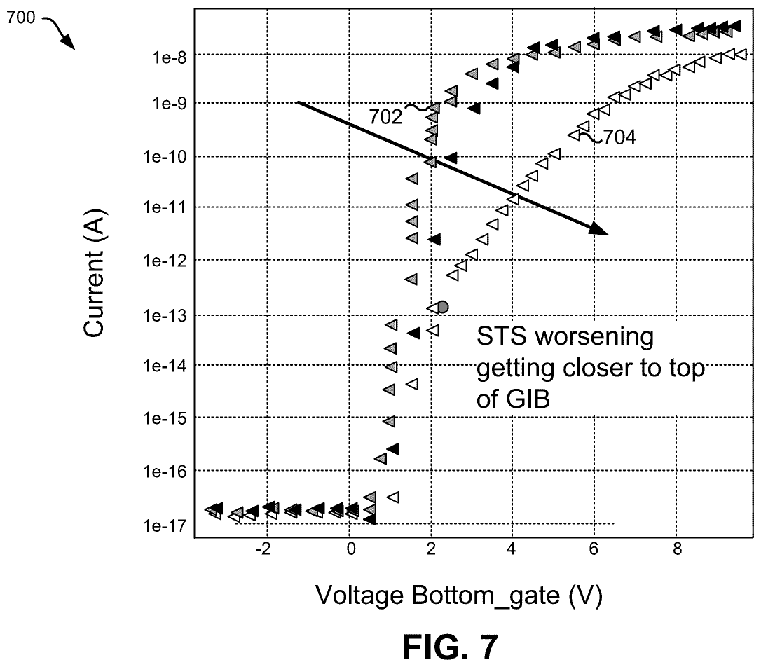

Referring back to FIG. 2, graph 200 shows how subthreshold slope can decrease with increasing concentration of oxygen vacancies. Plot 202 has the lowest concentration of oxygen vacancies and the largest subthreshold slope, whereas plot 206 has the highest concentration of oxygen vacancies and the smallest subthreshold slope. FIG. 7 illustrates a graph 700 that shows current-gate voltage characteristics for different thin film transistors consistent with the third approach according to some aspects of the present disclosure. The graph 700 includes plots for the bottom gate structure of dual-gate device 600 having different thicknesses for the top layer 608. Extreme cases are indicated by plot 702 and plot 704. Plot 702 is associated with a thick top layer 608 and thus has a steep subthreshold slope. Plot 704 is associated with a thin top layer 608 and has a shallow subthreshold slope.

Referring back to FIG. 6, the dual-gate device 600 can also include a top gate structure. The top gate structure can act as an S-TFT and can have a steeper subthreshold slope than the bottom gate structure. The top gate structure can include the semiconductor structure (including all components of the semiconductor structure), a top gate insulator 310, and a top conducting layer 312.

### IV. Approach #4: Addition of a Bottom Semiconductor Layer

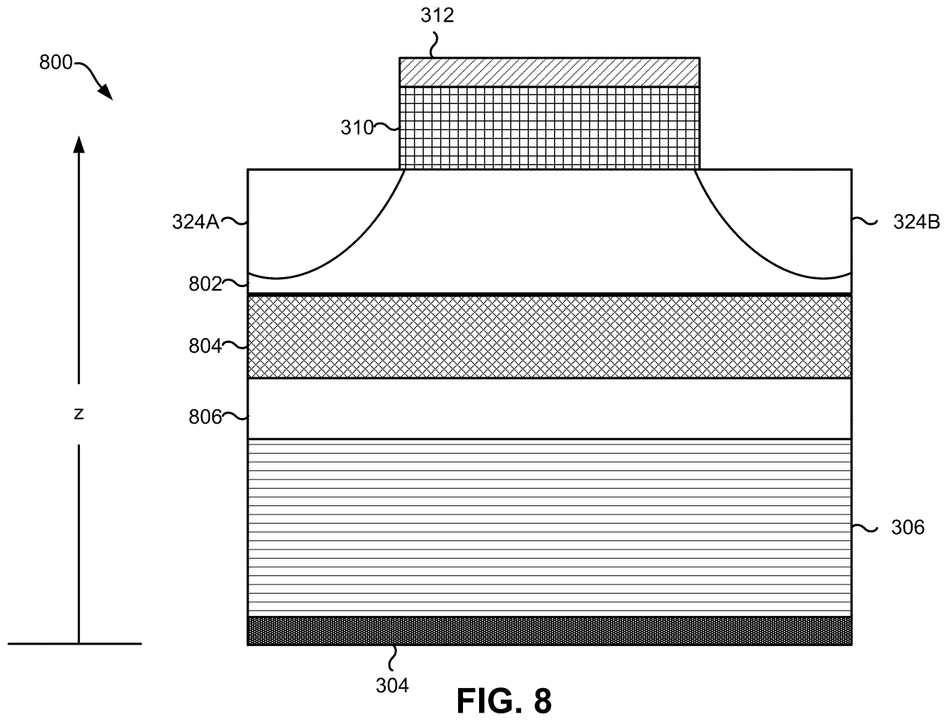

FIG. 8 is a cross-section of a dual-gate device 800 with a D-TFT bottom gate structure consistent with a fourth approach according to some aspects of the present disclosure. The dual-gate device 800 can include semiconductor structure. The fourth approach can involve adding an additional semiconductor layer 806 in the semiconductor structure to protect a semiconductor layer 804 with a main channel. The fourth approach can be combined with any of the other approaches, several of the other approaches, or all of the other approaches. The additional semiconductor layer can protect semiconductor layer 804 from diffusion of material from below the semiconductor layer 804. The semiconductor structure can include heavily doped regions referred to as a source region 324A and a drain region 324B.

The semiconductor structure can also include multiple semiconductor layers, such as semiconductor layer 802, semiconductor layer 804, and the additional semiconductor layer 806. In some examples, semiconductor layer 802 and additional semiconductor layer 806 can be made of a same material (e.g., IGZTO) and semiconductor layer 804 can be a different material. Semiconductor layers 802 and 806 in a form of IGTZO can prevent a migration of Oxygen to or from the semiconductor layer 804. Materials in semiconductor layer 802 and additional semiconductor layer 806 can have a larger bandgap than that of the material in semiconductor layer 804. In FIG. 8, the source region 324A and the drain region 324B are shown confined to the semiconductor layer 502 but the source region 324A and the drain region 324B can extend into the other semiconductor layers.

The dual-gate device 800 can also include a top gate structure and a bottom gate structure. The top gate structure can act as an S-TFT and can have a steeper subthreshold slope than the bottom gate structure. The top gate structure can include the semiconductor structure (including all components of the semiconductor structure), a top gate insulator 310, and a top conducting layer 312. The bottom gate structure can act as a D-TFT and can include the semiconductor structure (including all components of the semiconductor structure), a bottom gate insulator 306, and a bottom conducting layer 304. A coordinate z can define a height of a position within the dual-gate device 800.

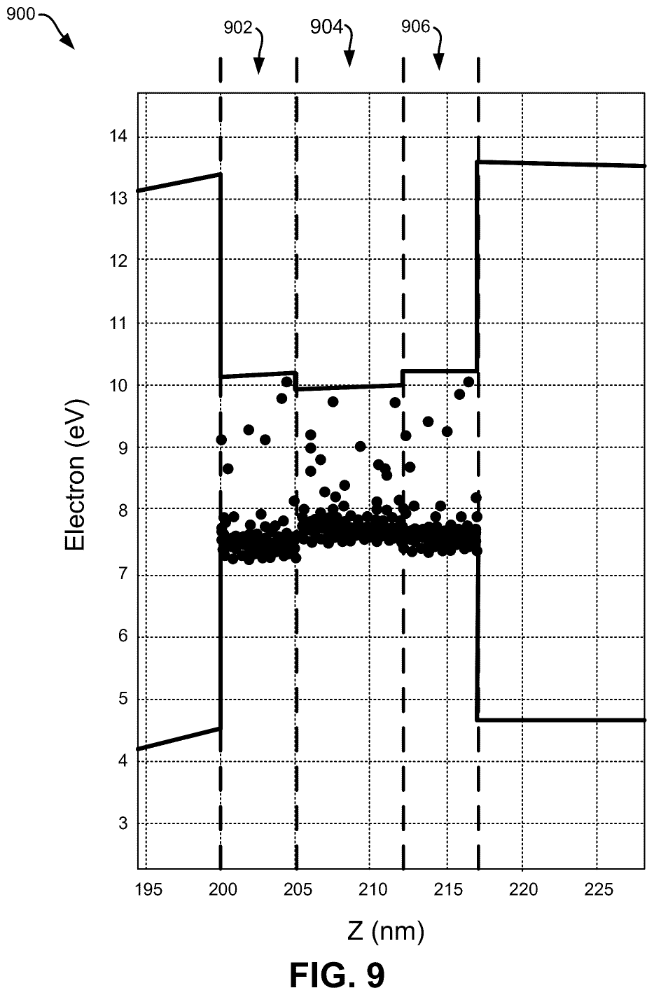

FIG. 9 is a graph 900 of energy band diagrams as a function of a coordinate z associated with a dual-gate device (e.g., dual-gate device 800 of FIG. 8) consistent with a fourth approach according to some aspects of the present disclosure. The coordinate z can be the coordinate z illustrated in FIG. 8. Since the dual-gate device 800 can include layers of different materials, the energy bands can depend on the coordinate z. The graph 900 can include three regions: region 902, region 904, and region 906. The three regions can be associated with three semiconductor layers of the dual-gate device 800.

Region 902 can be associated with an additional semiconductor layer 806. The additional semiconductor layer 806 can be beneath and protect semiconductor layer 804. Semiconductor layer 804 can include a main channel for the dual-gate device 800. Region 904 can be associated with semiconductor layer 804. Region 906 can be associated with semiconductor layer 802. From graph 900, the additional semiconductor layer 806 and the semiconductor layer 802 can have similar bandgaps that are larger than a bandgap associated with semiconductor layer 804. The larger bandgaps allow the additional semiconductor layer 806 and the semiconductor layer 802 to protect semiconductor layer 804 during fabrication process stages and from particle diffusion from below or above the semiconductor layer 804.

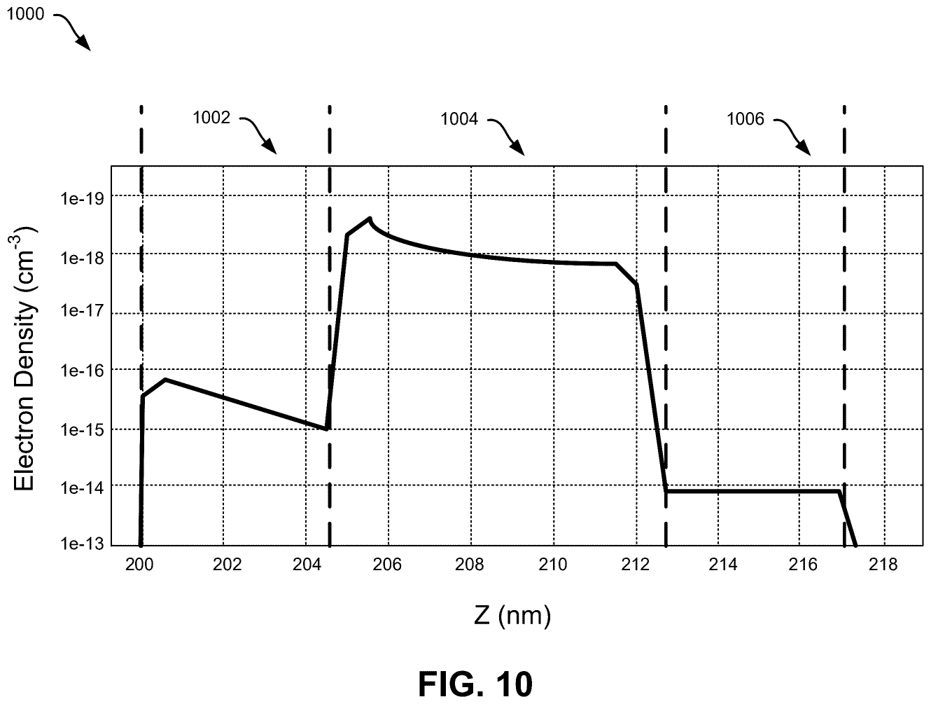

FIG. 10 is a graph 1000 of electron density as a function of a coordinate z associated with a dual-gate device (e.g., dual-gate device 800 of FIG. 8) consistent with a fourth approach according to some aspects of the present disclosure. The coordinate z can be the coordinate z illustrated in FIG. 8. Since the dual-gate device 800 can include layers of different materials, the electron density can depend on the coordinate z. The graph 1000 can include three regions: region 1002, region 1004, and region 1006. The three regions can be associated with three semiconductor layers of the dual-gate device 800.

Region 1002 can be associated with an additional semiconductor layer 806. The additional semiconductor layer 806 can be beneath and protect semiconductor layer 804. Region 1004 can be associated with semiconductor layer 804. Semiconductor layer 804 can have significantly higher values of electron density than the other semiconductor layers due to a smaller bandgap. Thus, semiconductor layer 804 can act as a main channel for the dual-gate device 800. Region 1006 can be associated with semiconductor layer 802. The additional semiconductor layer 806 and the semiconductor layer 802 can have similar bandgaps that are larger than a bandgap associated with semiconductor layer 804. The larger bandgaps allow the additional semiconductor layer 806 and the semiconductor layer 802 to protect semiconductor layer 804 during fabrication process stages and from particle diffusion from below or above the semiconductor layer 804.

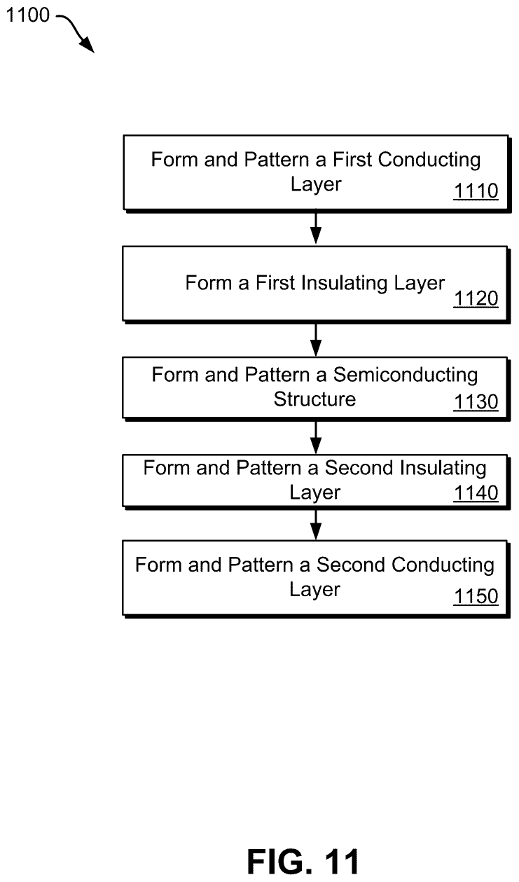

FIG. 11 is a flow chart of an example of a process 1100 for fabricating a dual-gate device according to some aspects of the present disclosure. The operations of the flowchart start at block 1110 and may be performed in the order indicated or in any suitable order. The operations of process 1100 can be performed in conjunction with operations associated with process 1200 or process 1300 described below.

At block 1110, the process 1100 involves forming and patterning a first conducting layer. The first conducting layer can be referred to as a bottom conducting layer. The first conducting layer can be formed on a buffer layer by sputter deposition and can have a thickness of about 100 nanometers. For example, the first conducting layer may have a thickness of between about 50 nm and about 60 nm, between about 60 nm and about 70 nm, between about 70 nm and about 80 nm, between about 80 nm and about 90 nm, between about 90 nm and about 1000 nm, between about 100 nm and about 110 nm, between about 110 nm and about 120 nm, between about 120 nm and about 130 nm, between about 130 nm and about 140 nm, and/or between about 140 nm and about 150 nm. The thickness of the first conducting layer may also be any combination of these ranges (e.g., between about 80 nm and about 120 nm). The thickness of the first conducting layer may also be any specific value within these ranges (e.g., about 105 nm). Examples of types of materials that can be used to form the first conducting layer can include metals (e.g., transition metals, rare earth metals, non-ferrous metals, ferrous metals) metal alloys, conducting polymers, etc. For example, the first conducting layer can be formed of molybdenum, chromium, gold, aluminum, copper, platinum, etc.

The first conducting layer can be patterned using an etching process, such as a dry etch process. A first portion of the patterned first conducting layer can form a base of the dual-gate device and define dimensions of the dual-gate device. For example, the base can have a width in a micron range of about 12 microns. For example, the base can have a width of between about 4 microns and about 6 microns, between about 6 microns and about 8 microns, between about 8 microns and about 10 microns, between about 10 microns and about 12 microns, between about 12 microns and about 14 microns, between about 14 microns and about 16 microns, between about 16 microns and about 18 microns, and/or between about 18 microns and about 20 microns. The width of the base may also be any combination of these ranges (e.g., between about 4 microns and about 20 microns). The width of the base may also be any specific value within these ranges (e.g., about 12 microns). A second portion of the first conducting layer can be accessed by a contact pad and provide electrical access to the first conducting layer. The first conducting layer can be a component of a first gate structure. The first gate structure can be a D-TFT.

At block 1120, the process 1100 involves forming a first insulating layer. The first insulating layer can be referred to as a bottom gate insulator. The first insulating layer can be formed from multiple layers. The first insulating layer can be a component of a D-TFT portion of the dual-gate structure and can be designed with a minimized capacitance. The effective dielectric constant of the first insulating layer can be lower than an effective dielectric constant of a second insulating layer of a S-TFT portion of the dual-gate device.

The first insulating layer can be thicker than the second insulating layer. For example, a thickness of the first insulating layer can be about 350 nm, and a thickness of the second insulating layer can be about 150 nm. For example, the first insulating layer can have a thickness of between about 300 nm and about 320 nm, between about 320 nm and about 340 nm, between about 340 nm and about 360 nm, between about 360 nm and about 380 nm, and/or between about 380 nm and about 400 nm. The thickness of the first insulating layer may also be any combination of these ranges (e.g., between about 300 nm and about 400 nm). The thickness of the first insulating layer may also be any specific value within these ranges (e.g., about 350 nm). For example, the second insulating layer can have a thickness of between about 100 nm and about 120 nm, between about 120 nm and about 140 nm, between about 140 nm and about 160 nm, between about 160 nm and about 180 nm, and/or between about 180 nm and about 200 nm. The thickness of the second insulating layer may also be any combination of these ranges (e.g., between about 100 nm and about 200 nm). The thickness of the first insulating layer may also be any specific value within these ranges (e.g., about 150 nm). Each layer of the multiple layers can be made from a low-k dielectric material. Examples of low k dielectrics include silicon oxide, porous silicon oxide, spin-on organic polymer films, spin-on silicon based polymeric dielectrics, air gaps, etc. In some examples, the first insulating layer can include three layers and at least one of the layers can have a different dielectric constant than the other layers. Forming the first insulating layer can involve growing silicon oxide layers. Additional details regarding a formation of the first insulating layer can be found below in descriptions of processes 1200 or 1300.

At block 1130, the process 1100 involves forming and patterning a semiconductor structure. The semiconductor structure of the dual-gate device can include heavily doped regions referred to as a source region and a drain region. The source and drain region can be formed by a plasma treatment. In some examples, the source and drain region can be formed after etching a second insulating layer and second conducting layer of the dual-gate structure. In some examples, the semiconductor structure can include multiple semiconductor layers. A first semiconductor layer can act as a main channel for both the first gate structure and a second gate structure. A second semiconductor layer can act as a protective layer that protects the first semiconductor layer from processing steps that can be detrimental to the first semiconductor layer. In some examples, the semiconductor structure can include a third semiconductor layer, under the first semiconductor layer/main channel layer, that can act as an additional protective layer. Each of the semiconductor layers can include the source or drain regions.

Materials that can form any of the semiconductor layers of the semiconductor structure can include metal oxide semiconductors, low temperature polysilicon (LTPS), etc. Examples of metal oxide semiconductors can include n-type metal oxide semiconductors, such as Indium Gallium Zinc Tin Oxide (IGZTO), Indium (III) Oxide (In₂O₃), Zinc Oxide (ZnO), or Tin (IV) Oxide (SnO₂). Examples of metal oxide semiconductors can also include p-type metal oxide semiconductors, such as Copper (II) Oxide (CuO), Nickel Oxide (NiO), Chromium Oxide (Cr₃O₄), or Cobalt (II, III) Oxide (Co₃O₄).

The separate layers of the semiconductor structure can be formed from a single semiconductor material, a single material formed from different deposition parameters in each layer, or from different materials. For example, the second and third semiconductor layers can be formed from a semiconducting material with a large bandgap relative to a bandgap of a semiconductor material used to form the first semiconductor layer. For example, the second and third semiconductor layers can be formed of IGTZO and can prevent a migration of Oxygen to or from the first semiconductor layer. Each semiconductor layer can be formed by Physical Vapor Deposition (PVD). The semiconductor layers can be patterned via an etching process, such as a wet etch process. Each of the semiconductor layers can be annealed. For example, the semiconductor layers can be annealed in a furnace at temperature of about 420° C. for an anneal time of about one hour. For example, the anneal temperature can be between about 360° C. and about 380° C., between about 380° C. and about 400° C., between about 400° C. and about 420° C., between about 420° C. and about 440° C., between about 440° C. and about 460° C., and/or between about 460° C. and about 480° C. The anneal temperature of the semiconducting layers may also be any combination of these ranges (e.g., between about 360° C. and about 480° C.). The anneal temperature of the semiconducting layers may also be any specific value within these ranges (e.g., about 420° C.).

At block 1140, the process 1100 involves forming and patterning a second insulating layer. The second insulating layer can be referred to as a top gate insulator. The second insulating layer can be formed from less layers than the first insulating layer (e.g., a single layer), more layers than the first insulating layer, or the same amount of layers as the first insulating layer. The second insulating layer can be a component of an S-TFT portion of the dual-gate structure and can be designed with a capacitance that is higher than the capacitance of the first insulating layer. Layers in the second insulating layer can be formed using high k materials.

Examples of high k dielectrics that can be used in forming the second insulating later include hafnium oxide, hafnium silicate, zirconium oxide, zirconium silicate, CeHfO₂, HfTiON, Er-HfO₂, etc. The effective dielectric constant of the second insulating layer can be higher than the effective dielectric constant of the first insulating layer of the D-TFT portion of the dual-gate device. Forming the second insulating layer can involve growing a single silicon oxide layer. The second insulating layer can be patterned by an etching process, such as a dry etch process. The second insulating layer can be etched before or after a second conducting layer of the dual-gate device is formed.

At block 1150, the process 1100 involves forming and patterning the second conducting layer. The second conducting layer can be referred to as a top conducting layer. The second conducting layer can be formed by a PVD process and can be a similar thickness as the first conducting layer. For example, the second conducting layer can have a thickness of about 150 nanometers. For example, the second conducting layer may have a thickness of between about 100 nm and about 120 nm, between about 120 nm and about 140 nm, between about 140 nm and about 160 nm, between about 160 nm and about 180 nm, and/or between about 180 nm and about 200 nm. The thickness of the second conducting layer may also be any combination of these ranges (e.g., between about 1000 nm and about 200 nm). The thickness of the first conducting layer may also be any specific value within these ranges (e.g., about 150 nm). The second conducting layer can be formed from the same material as the first conducting layer, or from a different material. For example, the first conducting layer can be formed from m and the second conducting layer can be formed from chromium.

The second conducting layer can be patterned using an etching process, such as a dry etch process. In some examples, the second insulating layer can be patterned together with the second conducting layer. A width of the second conducting layer can be less than the width of the first conducting layer to expose and access source and drain regions of the semiconductor structure. For example, the second conducting layer can have a width in a micron range, such as 6 microns. The second conducting layer can be a component of a second gate structure. The second gate structure can be an S-TFT.

In some examples, the process 1100 can also involve forming an ILD. The ILD can be a thick (˜400 nm) silicon oxide layer. For example, the ILD may have a thickness of between about 350 nm and about 370 nm, between about 370 nm and about 390 nm, between about 390 nm and about 410 nm, between about 410 nm and about 430 nm, and/or between about 430 nm and about 450 nm. The thickness of the ILD may also be any combination of these ranges (e.g., between about 350 nm and about 450 nm). The thickness of the first conducting layer may also be any specific value within these ranges (e.g., about 400 nm). The process 1100 can further involve etching the ILD directly above the source and drain regions, the second conducting layer, and the first conducting layer. To make electrical contact with the first conducting layer, a portion of the first insulating layer can also be etched. An additional conducting layer can be formed and pattern to create contact pads that make electrical contact with the source region, drain region, second conducting layer, and first conducting layer. After forming the contact pads, the dual-gate device can undergo an annealing process in air or vacuum.

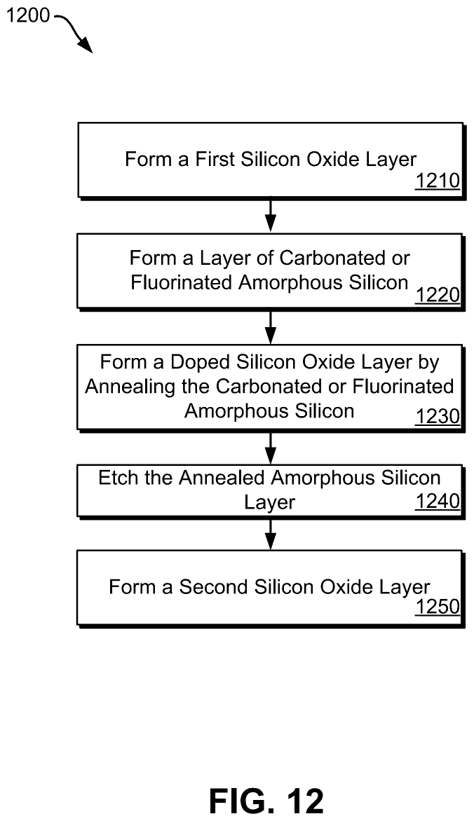

FIG. 12 is a flow chart of an example of a process 1200 for fabricating multiple dielectric layers of a first insulating layer in a dual-gate device according to some aspects of the present disclosure. The operations of the flowchart start at block 1210 and may be performed in the order indicated or in any suitable order. The operations of process 1200 can be performed in conjunction with operations associated with process 1100 described above or process 1300 described below.

At block 1210, the process 1200 involves forming a first silicon oxide layer. The first silicon oxide layer can be about 350 nm thick. For example, the first silicon oxide layer can have a thickness of between about 300 nm and about 320 nm, between about 320 nm and about 340 nm, between about 340 nm and about 360 nm, between about 360 nm and about 380 nm, and/or between about 380 nm and about 400 nm. The thickness of the first silicon layer may also be any combination of these ranges (e.g., between about 300 nm and about 400 nm). The thickness of the first silicon oxide layer may also be any specific value within these ranges (e.g., about 350 nm). In some examples, the first silicon oxide layer can be formed in two stages. In a first stage, a very thin (e.g., 5 nm) layer of silicon oxide can be deposited to form a good interface with a first conducting layer of a dual-gate device. For example, the very thin layer of silicon oxide can have a thickness of between about 5 nm and about 8 nm, between about 8 nm and about 11 nm, between about 11 nm and about 14 nm, between about 14 nm and about 17 nm, and/or between about 17 nm and about 20 nm. The thickness of the very thin layer of silicon oxide may also be any combination of these ranges (e.g., between about 5 nm and about 20 nm). The thickness of the very thin layer of silicon oxide may also be any specific value within these ranges (e.g., about 5 nm). In a second stage, another thicker layer of silicon oxide can be formed on top of the thinner layer of silicon oxide. Conversely, the first silicon oxide layer can be formed in a single stage.

At block 1220, the process 1200 involves forming a layer of carbonated or fluorinated amorphous silicon. The layer can be an alloy of amorphous silicon and carbon (amorphous silicon-carbide) or amorphous silicon and fluorine. Other materials may be present in the alloy layer as well. For example, the amorphous alloy may be hydrogenated.

At block 1230, the process 1200 involves forming a doped silicon oxide layer by annealing the carbonated or fluorinated amorphous silicon layer. Annealing the carbonated or fluorinated amorphous silicon layer can cause carbon or fluorine atoms to diffuse into at least a portion of the silicon oxide layer to form a doped silicon oxide layer. The doped silicon oxide layer can have a smaller dielectric constant than silicon oxide. For example, silicon oxide can have a dielectric constant of about 3.9, whereas fluorine doped silicon oxide can have a dielectric constant of about 3.5 and carbon doped silicon oxide can have a dielectric constant of about 3.0. For example, the fluorine doped silicon oxide can have a dielectric constant of between about 3.1 and about 3.3, between about 3.3 and about 3.5, between about 3.5 and about 3.7, and/or between about 3.7 and about 3.9. The dielectric constant of fluorine doped silicon oxide may also be any combination of these ranges (e.g., between about 3.1 and 3.9). The dielectric constant of fluorine doped silicon oxide may also be any specific value within these ranges (e.g., about 3.5). For example, the carbon doped silicon oxide can have a dielectric constant of between about 2.7 and about 2.9, between about 2.9 and 3.1, between about 3.1 and about 3.3, between about 3.3 and about 3.5, between about 3.5 and about 3.7, and/or between about 3.7 and about 3.9. The dielectric constant of carbon doped silicon oxide may also be any combination of these ranges (e.g., between about 2.7 and 3.9). The dielectric constant of carbon doped silicon oxide may also be any specific value within these ranges (e.g., about 3.1).

At block 1240, the process 1200 involves etching the annealed amorphous silicon layer. The etching of the amorphous silicon layer can be performed in such a way that the silicon oxide layer(s) are not affected. The amorphous silicon layer can be removed by a dry or wet etch process.

At block 1250, the process 1200 involves forming a second silicon oxide layer. The second silicon oxide layer can be formed on top of the doped silicon oxide layer. The second silicon oxide can be a very thin layer to form a good interface with a semiconductor structure of the dual-gate device. For example, the second silicon oxide layer can have a thickness of between about 5 nm and about 8 nm, between about 8 nm and about 11 nm, between about 11 nm and about 14 nm, between about 14 nm and about 17 nm, and/or between about 17 nm and about 20 nm. The thickness of the second silicon oxide layer may also be any combination of these ranges (e.g., between about 5 nm and about 20 nm). The thickness of the second silicon oxide layer may also be any specific value within these ranges (e.g., about 5 nm).

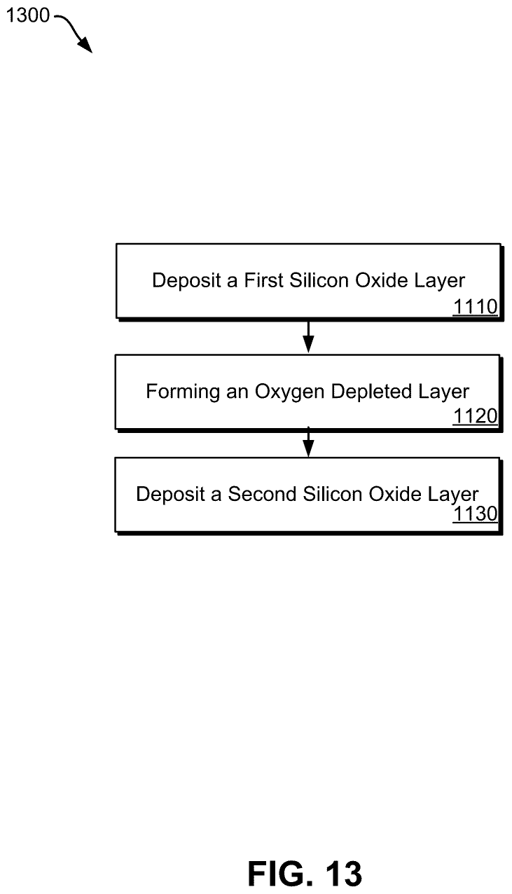

FIG. 13 is a flow chart of an example of a process 1300 for fabricating a first insulating layer having an oxygen depleted layer in a dual-gate device according to some aspects of the present disclosure. The operations of the flowchart start at block 1310 and may be performed in the order indicated or in any suitable order. The operations of process 1300 can be performed in conjunction with operations associated with process 1100 or process 1200 described above.

At block 1310, the process 1300 involves forming a first silicon oxide layer. The first silicon oxide layer can be about 350 nm thick. For example, the first silicon oxide layer can have a thickness of between about 300 nm and about 320 nm, between about 320 nm and about 340 nm, between about 340 nm and about 360 nm, between about 360 nm and about 380 nm, and/or between about 380 nm and about 400 nm. The thickness of the first silicon layer may also be any combination of these ranges (e.g., between about 300 nm and about 400 nm). The thickness of the first silicon oxide layer may also be any specific value within these ranges (e.g., about 350 nm). In some examples, the first silicon oxide layer can be formed in two stages. In a first stage, a very thin layer of silicon oxide can be deposited to form a good interface with a first conducting layer of a dual-gate device. In a second stage, another thicker layer of silicon oxide can be formed on top of the thinner layer of silicon oxide. Conversely, the first silicon oxide layer can be formed in a single stage.

At block 1320, the process 1300 involves forming an oxygen depleted layer. The oxygen depleted layer can be formed in a similar manner as the first silicon oxide layer but a silicon to oxygen ratio can be tuned to reduce an amount of oxygen in the layer. For instance, instead of a 1:2 silicon to oxygen ratio, the silicon to oxygen ratio can be about 1:1.5 while the oxygen depleted layer is formed. For example, the silicon to oxide ratio during the oxygen depleted layer formation can have a value of between about 1:1 and about 1:1.3, between about 1:1.3 and about 1:1.5, between about 1:1.5 and about 1:1.7, and/or between about 1:1.7 and about 1:1.9. The silicon to oxide ratio may also be any combination of these ranges (e.g., between about 1:1.1 and about 1:1.9). The silicon to oxide ratio may also be any specific value within these ranges (e.g., about 1:1.5). Alternatively, or additionally, the oxygen depleted layer can be formed from pulsed laser deposition. For example, the oxygen depleted layer can be a titanium oxide (TiO₂) thin film formed as a monolayer from a single laser pulse. A higher concentration in oxygen vacancies can lead to a greater reduction in the subthreshold slope of the bottom gate structure.

At block 1330, the process 1300 involves forming a second silicon oxide layer. The second silicon oxide layer can be formed on top of the doped silicon oxide layer. The second silicon oxide can be a very thin layer to form a good interface with a semiconductor structure of the dual-gate device.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A dual-gate device comprising:
a first gate structure comprising:
a first conducting layer;
a first insulating layer beneath the first conducting layer; and
a semiconductor structure under the first insulating layer, the semiconductor structure comprising a source and drain region; and
a second gate structure comprising:
the semiconductor structure;
a second insulating layer under the semiconductor structure, the second insulating layer comprising a plurality of dielectric layers, at least one layer of the plurality of dielectric layers having a different dielectric constant than any other layer in the plurality of dielectric layers; and
a second conducting layer beneath the second insulating layer.

2. The dual-gate device of claim 1, wherein the first gate structure comprises a steeper subthreshold slope than the second gate structure.

3. The dual-gate device of claim 1, wherein the first insulating layer comprises a larger dielectric constant than an effective dielectric constant of the second insulating layer.

4. The dual-gate device of claim 1, wherein the plurality of dielectric layers comprises three dielectric layers.

5. The dual-gate device of claim 4, wherein the three dielectric layers comprise a first silicon oxide layer, a doped silicon oxide layer, and a second silicon oxide layer.

6. The dual-gate device of claim 5, wherein the doped silicon oxide layer is doped with carbon or fluorine.

7. The dual-gate device of claim 4, wherein the three dielectric layers comprise a first silicon oxide layer, an oxygen depleted layer, and a second silicon oxide layer.

8. The dual-gate device of claim 7, wherein the first or the second silicon oxide layer is less than about 20 nanometers thick.

9. The dual-gate device of claim 1, wherein the semiconductor structure comprises a first metal oxide semiconductor thin film and a second metal oxide semiconductor thin film under the first metal oxide semiconductor thin film.

10. The dual-gate device of claim 9, the semiconductor structure comprises a third metal oxide semiconductor thin film under the second metal oxide semiconductor thin film.

11. The dual-gate device of claim 10, wherein the third metal oxide semiconductor thin film is identical to the first metal oxide semiconductor thin film.

12. A method for fabricating a dual-gate device, the method comprising:
forming a first gate structure by:
forming and patterning a first conducting layer;
forming a first insulating layer, the first insulating layer comprising a plurality of dielectric layers, at least one layer of the plurality of dielectric layers having a different dielectric constant than any other layer in the plurality of dielectric layers; and
forming and patterning a semiconductor structure, the semiconductor structure comprising a source and drain region; and
forming a second gate structure by:
forming and patterning a second insulating layer; and
forming and patterning a second conducting layer.

13. The method of claim 12, wherein the plurality of dielectric layers comprises three dielectric layers.

14. The method of claim 13, wherein the three dielectric layers comprise a first silicon oxide layer, a doped silicon oxide layer, and a second silicon oxide layer.

15. The method of claim 14, wherein forming the first insulating layer comprises:
forming a first silicon oxide layer;
forming a layer of carbonated or fluorinated amorphous silicon;
forming a doped silicon oxide layer from at least a portion of the first silicon oxide layer by annealing the carbonated or fluorinated amorphous silicon, the doped silicon oxide layer being doped with carbon or fluorine;
etching the annealed amorphous silicon layer; and
forming a second silicon oxide layer.

16. The method of claim 13, wherein forming the first insulating layer comprises:
forming a first silicon oxide layer;
forming an oxygen depleted layer; and
forming a second silicon oxide layer.

17. The method of claim 16, wherein forming the oxygen depleted layer comprises forming the oxygen depleted layer by adjusting a silicon to oxygen ratio in a silicon oxide forming process or by depositing a titanium oxide layer with at least one pulse of a laser.

18. The method of claim 16, wherein the first or second silicon oxide layer is less than 20 nanometers thick.

19. The method of claim 12, wherein forming and patterning the semiconductor structure comprises:
forming and patterning a first metal oxide semiconductor thin film;
forming and patterning a second metal oxide semiconductor thin film; and
forming and patterning a third metal oxide semiconductor thin film, the third metal oxide semiconductor thin film being formed under the first metal oxide semiconductor thin film.

20. The method of claim 19, wherein the third metal oxide semiconductor thin film is identical to the first or second metal oxide semiconductor thin film.
